(19) United States
(12) Patent Application Publication
(10) Pub. No.: US 2026/0182464 A1
(43) Pub. Date: Jun. 25, 2026

(54) SEMICONDUCTOR DEVICE ASSEMBLIES WITH ALUMINUM NITRIDE HYBRID BONDS AND METHODS OF FORMING THE SAME

(71) Applicant: Micron Technology, Inc., Boise, ID (US)

(72) Inventors: Wei Zhou, Boise, ID (US); Vladimir Noveski, San Diego, CA (US); Amy R. Griffin, Boise, ID (US)

(21) Appl. No.: 19/370,613

(22) Filed: Oct. 27, 2025

Related U.S. Application Data
(60) Provisional application No. 63/737,489, filed on Dec. 20, 2024.

(51) Int. Cl. H01L 25/065; H01L 23/00; H01L 25/00; H01L 25/18; H10B 80/00

(52) U.S. Cl. CPC H10W 90/00; H10B 80/00; H10W 72/923; H10W 72/952; H10W 80/312; H10W 80/327; H10W 90/288; H10W 90/291; H10W 90/297; H10W 90/792

(57) ABSTRACT

A semiconductor device assembly is provided, comprising a first semiconductor device having an upper surface at which are disposed a first plurality of coplanar metal contact structures and a first aluminum nitride bonding surface and a second semiconductor device having a lower surface at which are disposed a second plurality of coplanar metal contact structures and a second aluminum nitride bonding surface. Each of the first plurality of coplanar metal contact structures are directly bonded to a corresponding one of the second plurality of coplanar metal contact structures by a metal-metal bond, and the first aluminum nitride bonding surface is directly bonded to the second aluminum nitride bonding surface by a fusion bond.

### CROSS-REFERENCE TO RELATED APPLICATION(S)

The present application claims priority to U.S. Provisional Patent Application No. 63/737,489, filed Dec. 20, 2024, the disclosure of which is incorporated herein by reference in its entirety.

### TECHNICAL FIELD

The present disclosure generally relates to semiconductor device assemblies, and more particularly relates to semiconductor device assemblies with aluminum nitride (AlN) hybrid bonds and methods of forming the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 through 8 are simplified schematic cross-sectional views of a semiconductor device assembly being fabricated in accordance with embodiments of the present technology.

FIG. 9 is a simplified schematic cross-sectional view of a semiconductor device in accordance with an alternative embodiment of the present technology.

FIG. 10 is a flow chart illustrating a method of making a semiconductor device assembly in accordance with an embodiment of the present technology.

FIG. 11 is a schematic view showing a system that includes a semiconductor device assembly configured in accordance with an embodiment of the present technology.

### DETAILED DESCRIPTION

Some packaged semiconductor devices include multiple devices arranged in a die stack, with each device electrically and mechanically coupled to an adjacent device by a hybrid bond, in which coplanar metal pads and a dielectric bonding surface of one device are joined by metal-metal bonds and dielectric-dielectric bonds, respectively, to corresponding coplanar metal pads and a dielectric bonding surface of an adjacent device. The dielectric material at the bond interface may be silicon oxide, silicon nitride, silicon carbon nitride, etc. A drawback of these dielectric materials is their relatively low thermal conductivity-on the order of around 1 W/mK. For higher performance semiconductor devices that generate waste heat during operation and may rely upon the vertical transportation of thermal energy through the vertical die stack to extract heat from the assembly, such low thermal conductivity poses a packaging challenge.

To address these drawbacks and others, various embodiments of the present application provide semiconductor device assemblies with highly thermally conductive dielectric material at a hybrid bonding interface between devices in a stack, such as aluminum nitride (AlN). AlN enjoys a thermal conductivity about two orders higher than the aforementioned dielectric materials (e.g., between about 150 and 250 W/mK), and provides a dramatic improvement in the vertical conduction of thermal energy through a device stack. The AlN material may be the only dielectric material between the bulk semiconductor material of a device substrate (e.g., silicon) and the bonding interface, or may be one of a plurality of layers of dielectric material between the bulk semiconductor material and the bonding interface.

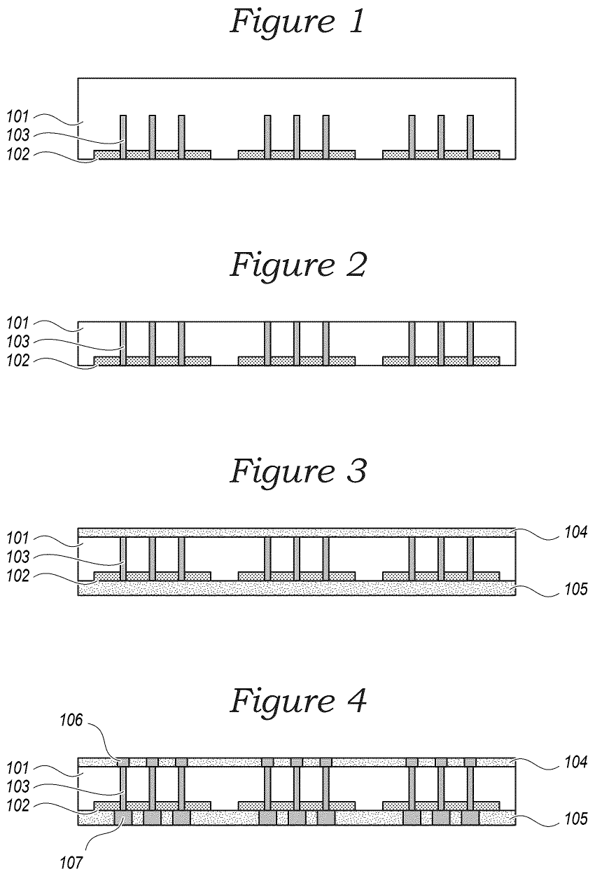

FIGS. 1-8 are simplified schematic cross-sectional views of a semiconductor device assembly being fabricated in accordance with embodiments of the present technology. As can be seen with reference to FIG. 1, a wafer 101 is provided, in which a plurality of active circuitry regions 102 correspond to eventual semiconductor die locations. A plurality of still-buried through silicon vias (TSVs) 103 are connected to the active circuitry regions 102 and embedded to an intermediate depth of the bulk semiconductor material (e.g., silicon) of the wafer 101. As shown in FIG. 2, the wafer 101 can be back-ground to reduce the thickness of the bulk semiconductor material and expose the TSVs 103. In FIG. 3, front and rear aluminum nitride layers 105 and 104, respectively, are disposed on the active and back side of the wafer, respectively. The aluminum nitride material can be disposed over the corresponding surfaces by one or more of a variety of processes, including atomic layer deposition (ALD), physical vapor deposition (PVD), chemical vapor deposition (CVD), and/or sputtering. As shown in FIG. 4, to facilitate electrical connection of the active circuitry regions 102 and TSVs 103, frontside and backside electrical contacts 107 and 106, respectively, are formed in the front and rear aluminum nitride layers 105 and 104 (e.g., by patterning, etching, and plating operations, as are well-understood by those of relevant skill in the art). Following the formation of frontside and backside electrical contacts 107 and 106, the surfaces of wafer 101 can be prepared for hybrid bonding (e.g., by chemical mechanical polishing (CMP), plasma activation, and rinsing, as will be well-understood by those of relevant skill in the art).

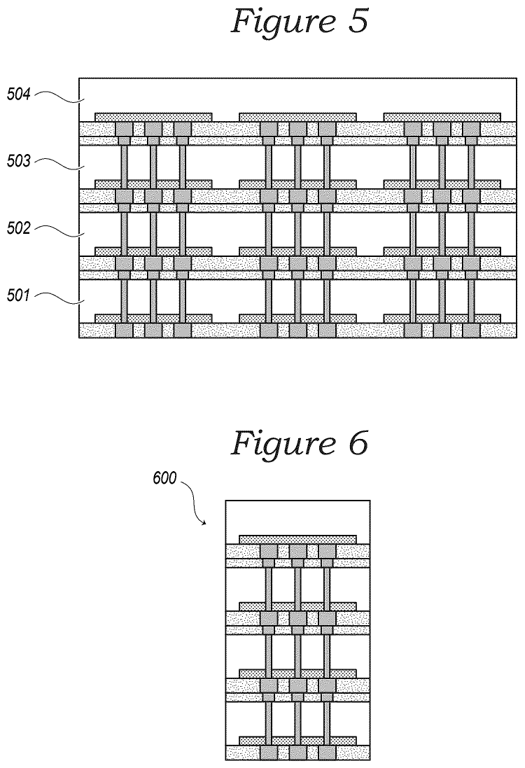

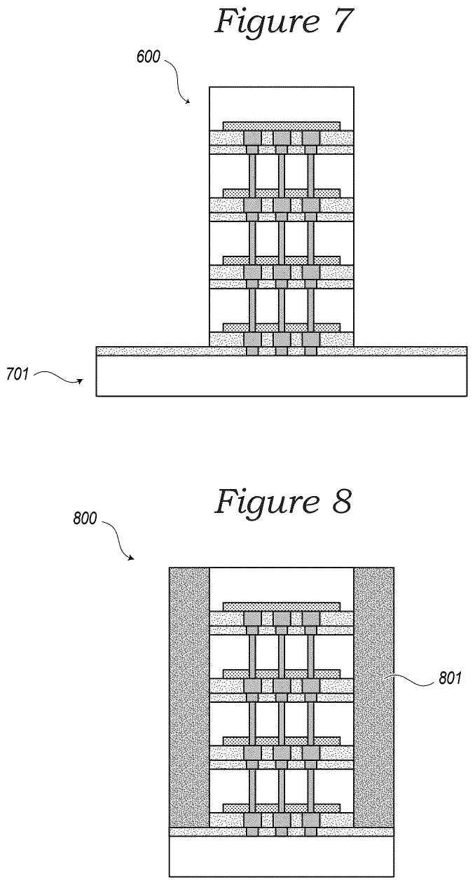

As shown in FIG. 5, a plurality of similar wafers 501-504 can be bonded together by forming hybrid bonds therebetween, in which the frontside and backside electrical contacts of facing wafers are bonded by metal-metal bonds, while the aluminum nitride material of the facing wafers are fusion bonded together (e.g., by alignment, bond wave initiation, and annealing processes, as will be well-understood by those of relevant skill in the art). Subsequently, as shown in FIG. 6, the wafer stack of FIG. 5 can be singulated into a plurality of die stacks, such as die stack 600. In an alternative embodiment, the wafer of FIG. 4 may be singulated prior to stacking a plurality of singulated dies to arrive at a similar structure (e.g., to identify and stack “known good” dies for improved yields). The die stack 600 can similar be bonded to another device 701 (e.g., an interface die, a logic die such as a controller, or a package-level substrate) with another hybrid bond including a fusion bond between facing aluminum nitride regions, as shown in FIG. 7.

In accordance with another aspect of the present disclosure, an assembly may further include an encapsulating mold material that surrounds at least the sidewalls of at least some of the devices in an assembly. For example, FIG. 8 is a simplified schematic cross-sectional view of a semiconductor device assembly 800 in accordance with embodiments of the present technology in which the an encapsulating mold material 801 surrounds the sidewalls of a stack of semiconductor devices (e.g., memory dies) carried by a larger semiconductor device (e.g., a logic die such as a memory controller, an interface die, or a processor) bonded to one another by hybrid bonds include an aluminum nitride bonding material.

Although in the foregoing example embodiment semiconductor device assemblies have been illustrated and described as including a single first semiconductor device (with a first footprint) carrying four second semiconductor devices (with a second smaller footprint), in other embodiments other package arrangements may include a greater or lesser number of dies of greater or fewer sizes, mutatis mutandis.

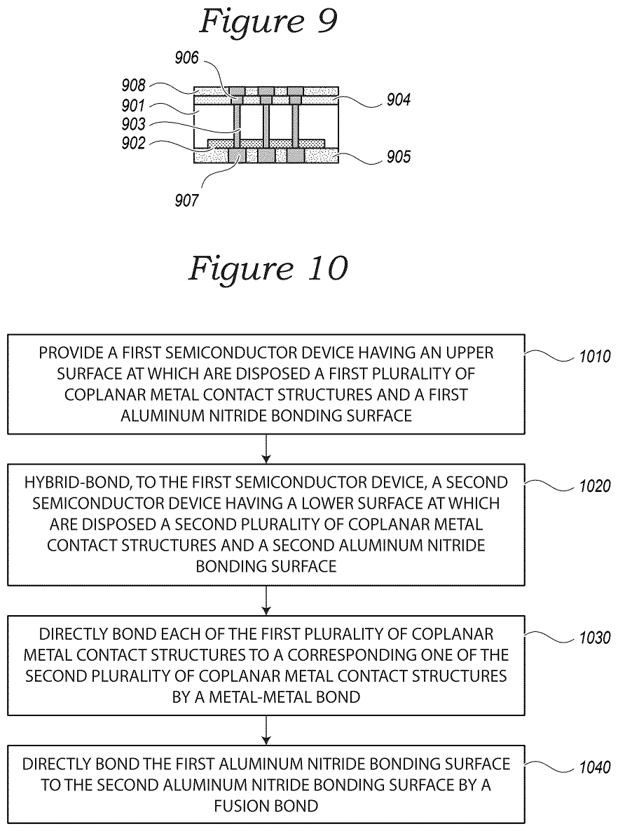

Although in the foregoing example embodiment semiconductor devices have been illustrated and described as including an aluminum nitride bonding layer in direct contact with a bulk semiconductor material of the device, in other embodiments semiconductor devices can include other dielectric materials interposed between the aluminum nitride layer and the bulk semiconductor material. For example, FIG. 9 illustrates a semiconductor device in which a backside TSV 903 reveal process has included the formation of a dielectric layer 904 include one or more materials other than aluminum nitride (e.g., silicon oxide, silicon nitride, silicon carbon nitride, etc.). Subsequent to the passivation of the backside of the substrate 901, an aluminum nitride layer 908 can be formed over the dielectric layer 904 (e.g., by atomic layer deposition (ALD), physical vapor deposition (PVD), chemical vapor deposition (CVD), and/or sputtering). Backside electrical contacts 906 can be formed through both the aluminum nitride layer 908 and the dielectric layer 904 (e.g., by a dual-damascene process) to connect TSVs 903 to the active circuitry 902 at the front side of the substrate 901, where an additional aluminum nitride layer 905 can be provided, and in which frontside electrical contacts 907 can be formed. Although not illustrated in FIG. 9, in other embodiments the front aluminum nitride layer 905 can additionally or alternatively be spaced apart from the bulk semiconductor material of substrate 901 by another dielectric layer.

Although in the foregoing example embodiments semiconductor device assemblies have been illustrated and described as including semiconductor devices bonded with hybrid bonds that include aluminum nitride bonding layers on both side of the bond line, in other embodiments semiconductor devices may be bonded by hybrid bonds that include an aluminum nitride bonding layer on one side of the bond line and a different dielectric material on the other side, such as silicon oxide, silicon nitride, silicon carbon nitride, etc.

In accordance with one aspect of the present disclosure, the semiconductor devices illustrated in the assemblies of FIGS. 1-9 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

FIG. 10 is a flow chart illustrating a method of making a semiconductor device assembly. The method may include providing a first semiconductor device having an upper surface at which are disposed a first plurality of coplanar metal contact structures and a first aluminum nitride bonding surface (box 1010). The method may further include hybrid-bonding, to the first semiconductor device, a second semiconductor device having a lower surface at which are disposed a second plurality of coplanar metal contact structures and a second aluminum nitride bonding surface (box 1020). The hybrid-bonding of box 1020 may include directly bonding each of the first plurality of coplanar metal contact structures to a corresponding one of the second plurality of coplanar metal contact structures by a metal-metal bond (box 1030) and directly bonding the first aluminum nitride bonding surface to the second aluminum nitride bonding surface by a fusion bond (box 1040).

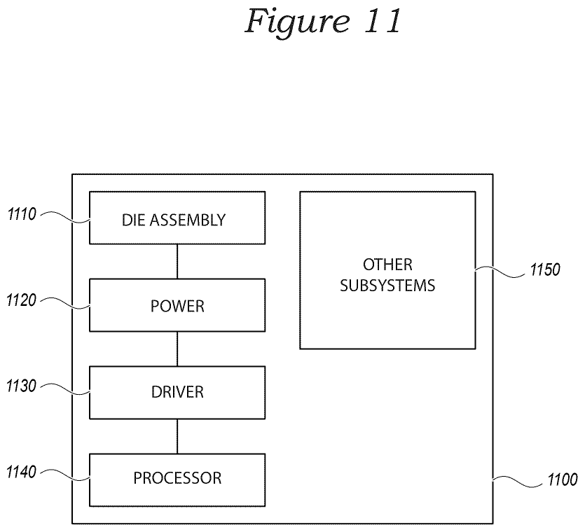

Any one of the semiconductor devices and semiconductor device assemblies described above with reference to FIGS. 1-10 can be incorporated into any of a myriad of larger and/or more complex systems, a representative example of which is system 1100 shown schematically in FIG. 11. The system 1100 can include a semiconductor device assembly (e.g., or a discrete semiconductor device) 1102, a power source 1104, a driver 1106, a processor 1108, and/or other subsystems or components 1110. The semiconductor device assembly 1102 can include features generally similar to those of the semiconductor devices described above with reference to FIGS. 1-10 The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, vehicles, appliances and other products. Components of the system 1100 may be housed in a single unit or distributed over multiple, interconnected units (e.g., through a communications network). The components of the system 1100 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor device having an upper surface at which are disposed a first plurality of coplanar metal contact structures and a first aluminum nitride bonding surface; and
a second semiconductor device having a lower surface at which are disposed a second plurality of coplanar metal contact structures and a second aluminum nitride bonding surface,
wherein each of the first plurality of coplanar metal contact structures are directly bonded to a corresponding one of the second plurality of coplanar metal contact structures by a metal-metal bond, and
wherein the first aluminum nitride bonding surface is directly bonded to the second aluminum nitride bonding surface by a fusion bond.

2. The semiconductor device assembly of claim 1, wherein the first semiconductor device is a logic die and the second semiconductor device is a memory die.

3. The semiconductor device assembly of claim 1, further comprising an encapsulant material surrounding sidewalls of at least the second semiconductor device.

4. The semiconductor device assembly of claim 1, further comprising a third semiconductor device bonded to the second semiconductor device by a hybrid bond including bonded aluminum nitride regions.

5. The semiconductor device assembly of claim 1, wherein the first aluminum nitride bonding surface comprises an aluminum nitride material in direct contact with a bulk semiconductor material of the first semiconductor device.

6. The semiconductor device assembly of claim 1, wherein the first aluminum nitride bonding surface comprises an aluminum nitride material separated from a bulk semiconductor material of the first semiconductor device by a dielectric material.

7. A method of making a semiconductor device assembly, comprising:
providing a first semiconductor device having an upper surface at which are disposed a first plurality of coplanar metal contact structures and a first aluminum nitride bonding surface; and
hybrid-bonding, to the first semiconductor device, a second semiconductor device having a lower surface at which are disposed a second plurality of coplanar metal contact structures and a second aluminum nitride bonding surface, by:
directly bonding each of the first plurality of coplanar metal contact structures to a corresponding one of the second plurality of coplanar metal contact structures by a metal-metal bond, and
directly bonding the first aluminum nitride bonding surface to the second aluminum nitride bonding surface by a fusion bond.

8. The method of claim 7, wherein the first semiconductor device is a logic die and the second semiconductor device is a memory die.

9. The method of claim 7, further comprising disposing an encapsulant material around sidewalls of at least the second semiconductor device.

10. The method of claim 7, further comprising bonding a third semiconductor device to the second semiconductor device by n additional hybrid bond including bonded aluminum nitride regions.

11. A semiconductor device, comprising:
a semiconductor substrate including active circuitry at a first side and through-silicon vias (TSVs) extending from the first side to a second side opposite the first side;
a first aluminum nitride layer at the first side and defining an upper surface of the semiconductor device;
a first plurality of metal contact structures having upper surfaces coplanar with the upper surface of the semiconductor device;
a second aluminum nitride layer at the second side and defining a lower surface of the semiconductor device; and
a second plurality of metal contact structures having lower surfaces coplanar with the lower surface of the semiconductor device.

12. The semiconductor device of claim 11, wherein the first aluminum nitride layer is in direct contact with the semiconductor substrate.

13. The semiconductor device of claim 11, wherein the first aluminum nitride layer is separated from the semiconductor substrate by a dielectric material.

14. The semiconductor device of claim 11, wherein the second aluminum nitride layer is in direct contact with the semiconductor substrate.

15. The semiconductor device of claim 11, wherein the second aluminum nitride layer is separated from the semiconductor substrate by a dielectric material.
